(19) United States
(12) Patent Application Publication
(10) Pub. No.: US 2011/0062332 A1
(43) Pub. Date: Mar. 17, 2011

(54) Charge-Coupled Device Monitor and Lighting Device Thereof

(75) Inventors: Huang-Chen Guo, Kaoshiung (TW); Hsiang Mei Chiang, Taipei (TW)

(73) Assignee: UPEC Electronics Corp., Taipei (TW)

(21) Appl. No.: 12/784,626

(22) Filed: May 21, 2010

(30) Foreign Application Priority Data
Sep. 11, 2009 (TW) 098216868

(51) Int. Cl. H01L 31/167; H01L 33/58

(52) U.S. Cl. 250/332; 250/504 R

(57) ABSTRACT

The present invention discloses a charge-coupled device monitor, comprising a lighting device, at least one charge-coupled unit and a processing unit. The lighting device comprises an infrared light emitting diode, an electrical conducting unit and a light guiding unit. The infrared light emitting diode receives a power to emit a light. The electrical conducting unit is positioned on a side of the infrared light emitting diode, electrically connecting to the infrared light emitting diode to provide the power. The light guiding unit, positioned on the other side of the infrared light emitting diode, changes the projecting profile of the light to a predetermined projecting profile, which comprises at least one straight edge. The charge-coupled unit receive the light emitted by the lighting device in the predetermined projecting profile and transforms the light to at least one electrical signal. The processing unit electrically connecting to the charge-coupled unit transmits an image according to the electrical signal.

### PRIORITY CLAIM

The present application claims priority to Taiwan Patent Application No. 098216868, filed Sep. 11, 2009, which is incorporated by reference in its entirety.

### FIELD OF THE INVENTION

The present invention relates to a charge-coupled device monitor and lighting device thereof, especially relates to a charge-coupled device monitor producing light with an infrared light emitting diode and lighting device thereof.

### BACKGROUND OF THE INVENTION

Charge-coupled device (CCD) tells an image with the electrons raised by impacting photons in compliance with Photoelectric effect. Therefore, monitors using a charge-coupled device inevitably need additional lighting device configured nearby to compensate insufficient light coming from environment in night time. Current charge-coupled device monitor mostly adopts halogen lamps as the light source of the lighting device, however, due to the various defects the halogen lamps have, for example: the environmental consciousness violating elements, halogen, contained in the halogen lamps, great power consumption, short lifetime, poor assembly strength leading to fragility and raised maintenance difficulty, a new model of the lighting device is needed to develop.

For all kinds of industrial light source, light emitting diode (LED) is a cold light illuminator, with the natures of power saving, lower consumption, short time to work, halogen free and long life time. Since 20 contraries, the technical barrier of the blue LED is broken through, multi-colored and high-brightness LED is invented to be broadly applied to all kinds of products, such as displays, projectors and lighting devices, etc. Thus the lighting source attracting the most attentions to replace halogen lamps is LED to be a modern lighting source adopting in the charge-coupled device monitor. However, current technologies for fabrication and assembly process limit the emitting angle LED capable to provide, hence the projecting profile is narrowed and the conformity of the illuminance is effected. A lot of LEDs have to be configured to maintain the illuminance to desired level, however, this will cause the problem of huge power consumption. The power still cannot be saved.

Therefore, a charge-coupled device monitor in compliance with environmental consciousness uses reliable and long-lifetime lighting device is still in needs.

### SUMMARY OF THE INVENTION

An object of the present invention is to provide a light guiding unit to change the projecting profile of the infrared light emitting diode. A more variable projecting profile shape is provided to solve the problems of narrowed projecting angle or great power consumption induced by configuring more infrared light emitting diode in the conventional art.

Another object of the present invention is to apply the LED in charge-coupled device monitor, and through a light guiding unit to form at least one straight edge in the projecting profile to accumulate the projecting profiles of LEDs in a limited number to construct various light patterns. Hence, only fewer LEDs required to sustain the illuminance in a desired standard with the environmental-consciousness-compliant, reliable and long-lifetime lighting device.

According to an aspect of the invention, a lighting device is provided, comprising: an infrared light emitting diode, receiving a power to emit a light; and a light guiding unit, positioned on another side of the infrared light emitting diode, changing the projecting profile of the light to a predetermined projecting profile comprising at least one straight edge.

According to another aspect of the invention, a charge-coupled device monitor is provided, comprising: at least one lighting device, comprising an infrared light emitting diode, an electrical conducting unit and a light guiding unit, wherein the infrared light emitting diode receives a power to emit a light, the electrical conducting unit is positioned on a side of the infrared light emitting diode, electrically connecting to the infrared light emitting diode to provide the power, the light guiding unit is positioned on a side of the infrared light emitting diode, changing the projecting profile of the light to a predetermined projecting profile, and the predetermined projecting profile comprises at least one straight edge; at least one charge-coupled unit, receiving the light emitted by the lighting device in the predetermined projecting profile, transforming the light to at least one electrical signal; and a processing unit, electrically connecting the charge-coupled unit, transferring an image according to the electrical signal.

The lighting device may optionally comprise an electrical conducting unit positioned on a side of the infrared light emitting diode, electrically connecting to the infrared light emitting diode to provide the power.

The infrared light emitting diode is preferred to be the light source for the charge-coupled device monitor in night time. The predetermined projecting profile may be a distribution shape of the light in some distance, and it is preferred to be chosen from one of the following shapes comprising square like, rectangle and polygon, wherein square is the best in some embodiments. Hence, the conformity of the light projecting from the light guiding unit is promoted and the angle of the projecting profile is increased.

The assembly type of the light guiding unit and electrical conducting unit according to the present invention is not limited to Lumileds Luxeon assembly, surface mount assembly, Plastic Leaded Chip Carrier (PLCC) assembly, other types of assembly may be adopted in the present invention as well. The light guiding unit may have great transparency, and the electrical conducting unit may have great electrical conduction with the preference of comprising two electrode electrically connecting to the cathode and anode of the power, and connecting to the two ends of the LED(s) to provide the power.

The light guiding unit may be exemplified as a total internal reflection lens, which is made by any materials with great transparency, such as but is not limited to epoxy, acrylic or crystallized glass. Additionally, the light guiding unit also may be implemented with an integrated structure, monocoque, or the structure constructed by several parts. The light guiding unit may optionally further comprises a light entering area and a light exiting area, wherein the light entering area may be positioned beside the infrared light emitting diode in some embodiments. After the light enters the light guiding unit from light entering area, the light could be projected from the light exiting area with the predetermined projecting profile. The light entering area and light exiting area are preferred to have great transparency. In some embodiments, the light exiting area may comprise at least one flange and a convex lens forming within the flange, and within the flange and convex lens, at least one groove may be optionally formed. For the curvature radius of the convex lens, in some embodiments, it is better to be in the range of 5 to 5.3 mm; for the curvature radius of the groove, it may be in the range of 11 to 11.9 mm, whereas better in the range of 11.15 to 11.4 mm. Moreover, the diameter of the light exiting area may be in the range of 10.8 to 11.8 mm, and the distance between the infrared light emitting diode to the top of the convex lens may be in the range of 10.8 to 12 mm for example, or correspond to the focus of the convex lens in some embodiments.

For enhancing the thermal diffusivity, in some embodiments, it is preferred to position a buffer between the infrared light emitting diode and the light entering area, or a heat sink on the electrical conducting unit to couple to the infrared light emitting diode. However, it is not limited to such elements stated here, other elements with similar function can be adopted as well.

On the other hand, for enhancing light utilization efficiency, a reflective cup may be optionally positioned in the electrical conducting unit, and in one embodiment, the reflective cup is positioned next to the infrared light emitting diode for example. The light emitted from the side or near the bottom of the infrared light emitting diode is able to reflect to the light guiding unit.

The light guiding unit changes the projecting profile of the infrared light emitting diode to the shape comprising at least one straight edge, and expands the projecting angle of the light emitted by the infrared light emitting diode. Therefore, less number of LED(s) is needed to sustain illuminance in a required standard in the present invention, and power consumption is lowered, meanwhile, a lighting device in compliance with environmental consciousness and power saving is provided.

### BRIEF DESCRIPTION OF THE DRAWINGS

Various objects and advantages of the present invention will be more readily understood from the following detailed description when read in conjunction with the appended drawing, in which:

FIG. 1 shows a side view of a lighting device according to an embodiment of the present invention.

FIG. 2 shows a top view of the lighting device shown in FIG. 1.

FIG. 3 shows a cross-sectional view of the lighting device shown in FIG. 1 along the AA line.

FIG. 4 shows a top view of the lighting device shown in FIG. 1 after removing the light guiding unit.

FIG. 5 shows a 2-D distribution of illumination of a lighting device according to an embodiment of the present invention.

FIG. 6 shows a side view of a lighting device according to another embodiment of the present invention.

FIG. 7 shows a charge-coupled device monitor of an embodiment of the present invention.

FIG. 8 shows a systematic view of the charge-coupled device monitor shown in FIG. 7.

### DESCRIPTION OF EMBODIMENTS OF THE INVENTION

Reference will now be made in detail to the preferred embodiments of the present invention, examples of which are illustrated in the accompanying drawings. Elements drawn are not necessarily in a true scale, however, similar symbols or reference number usually refer to similar elements.

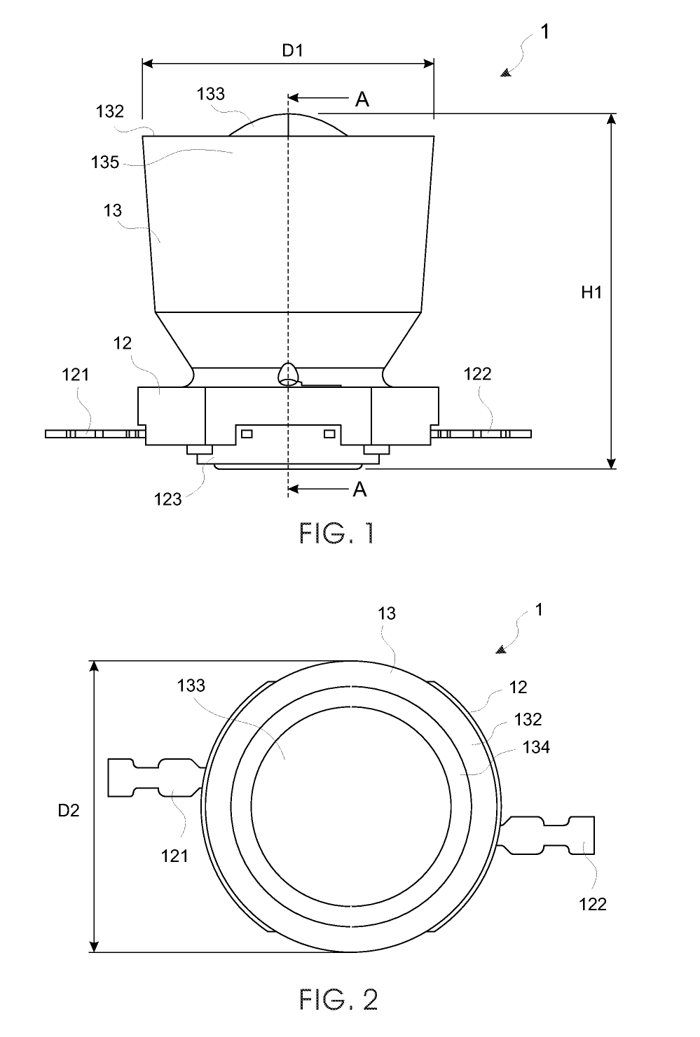

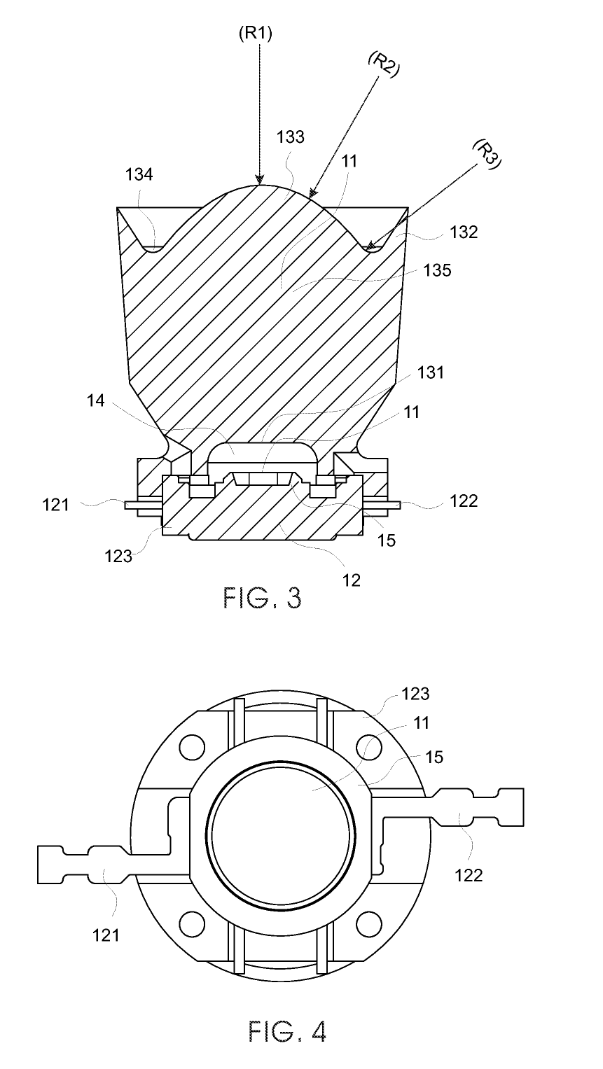

Please refer to FIGS. 1-4, wherein FIG. 1 shows a side view of a lighting device according to an embodiment of the present invention, FIG. 2 shows a top view of the lighting device shown in FIG. 1, FIG. 3 shows a cross-sectional view of the lighting device shown in FIG. 1 along the AA line, and FIG. 4 shows a top view of the lighting device shown in FIG. 1 after removing the light guiding unit. The lighting device 1 comprises an infrared light emitting diode 11, a electrical conducting unit 12, a light guiding unit 13, a buffer 14 and a reflective cup 15. The electrical conducting unit 12 is positioned at a side of the infrared light emitting diode 11, while the light guiding unit 13 is positioned at another side of the infrared light emitting diode 11. The assembly structure of the infrared light emitting diode 11 is formed by the electrical conducting unit 12 and the light guiding unit 13. In the present embodiment, the electrical conducting unit 12 and the light guiding unit 13 are connected to each other in a compact manner, and a receiving space is formed therein for receiving the infrared light emitting diode 11.

When the infrared light emitting diode 11 is powered by electricity, an infrared light is emitted. It is because that when the two ends of the LED is powered by electricity, among the pn junction between the p-type semiconductor and n-type semiconductor coupled to each other, a lot of electronic-hole pairs will be reconciled, and at this time, residual power will be released in photons manner to emit light. The electrical conducting unit 12 and the infrared light emitting diode 11 provide the required power to the infrared light emitting diode 11 to emit the light by electrically connection. In the present embodiment, the electrical conducting unit 12 comprises two electrodes 121, 122 and a base 123. The electrodes 121, 122 has great electric conduction and electrically connect to cathode and anode of an external power (not shown) respectively. On the base 123, at least one circuit is formed to electrically connect to the electrodes 121, 122 and the infrared light emitting diode 11. Thus a route for the external power to the infrared light emitting diode 11 is produced.

The light guiding unit 13 has great transparency, and it is preferred to be formed integrated into a monocoque or constructed by multiple parts. The light guiding unit 13 comprises a light entering area 131 and a light exiting area 135, wherein the light entering area 131 is next to the infrared light emitting diode 11, for example: the light entering area 131 is positioned above the infrared light emitting diode 11, and the light exiting area 135 is positioned on an end farer away from the infrared light emitting diode 11. So, after the light enters the light guiding unit 13 from the light entering area 131, the light guiding unit 13 will guide the direction of the light, whereas when the light is emitted from the light exiting area 135, the light guiding unit 13 changes the projecting profile of the light to a predetermined projecting profile. The predetermined projecting profile may be a distribution shape of the illuminance of the light in some distance, having at least one straight edge. Therefore, the projecting profile is friendly to be accumulated. In the present embodiment, the light guiding unit 13 is exemplified as a total internal reflection lens to product a total internal reflection effect upon the light entering the light guiding unit 13 when the light contacts with the sidewall of the light guiding unit 13, so the proportion of the light emitting from the light exiting area 135 is increased. The material of the light guiding unit 13 can be any material with great transparency, such as any of epoxy, acrylic or crystallized glass.

The light exiting area 131 comprises at least one flange 132 and a convex lens 133 formed within the flange 132. Between the flange 132 and convex lens 133, at least one groove 134 is optionally formed. Because the appearance of the light guiding unit 13 will effect the optical effects of the projecting profile, so height H1 of the lighting device 1, diameter D1, D2 of the light exiting area 135, curvature radius R1 of the top of the convex lens 133, curvature radius R2 of the side of the convex lens 133 and curvature radius R3 of the groove 134 are all important parameters. The height H1 of the lighting device 1 can be in the range of 14 to 14.4 mm, the distance between the infrared light emitting diode 11 to the top of the convex lens 133 corresponds to the focus of the convex lens 133, the diameter D1, D2 of the light exiting area is in the range of 10.8 to 11.8 mm, and preferably, the diameter D1, D2 of the light exiting area 135 is in the range of 11 to 11.6 mm. On the other hand, the curvature radius R1, R2 of the convex lens 133 is better to be in the range of 5 to 5.3 mm, the curvature radius R3 of the groove 134 is in the range of 11 to 11.9 mm, and preferably, the curvature radius R3 of the groove 134 is in the range of 11.15 to 11.4 mm. The buffer 14 is positioned between the infrared light emitting diode 11 and the light entering area of the light guiding unit 13 to enhance the thermal dissipation of the infrared light emitting diode 11. The buffer 14 can be chosen from the materials with great heat conduction and transparency, such as: silicon, to reduce the light covering effect for the light emitted from the infrared light emitting diode 11.

The reflective cup 15 is positioned in the electrical conducting unit 12, and the reflective cup 15 is positioned next to the infrared light emitting diode 11. The surface of the reflective cup 15 is smooth, so the reflective cup 15 is able to reflect the light emitted from the side or the bottom of the infrared light emitting diode 11 to the light guiding unit 13. The light utilization efficiency of the infrared light emitting diode 11 is hence promoted.

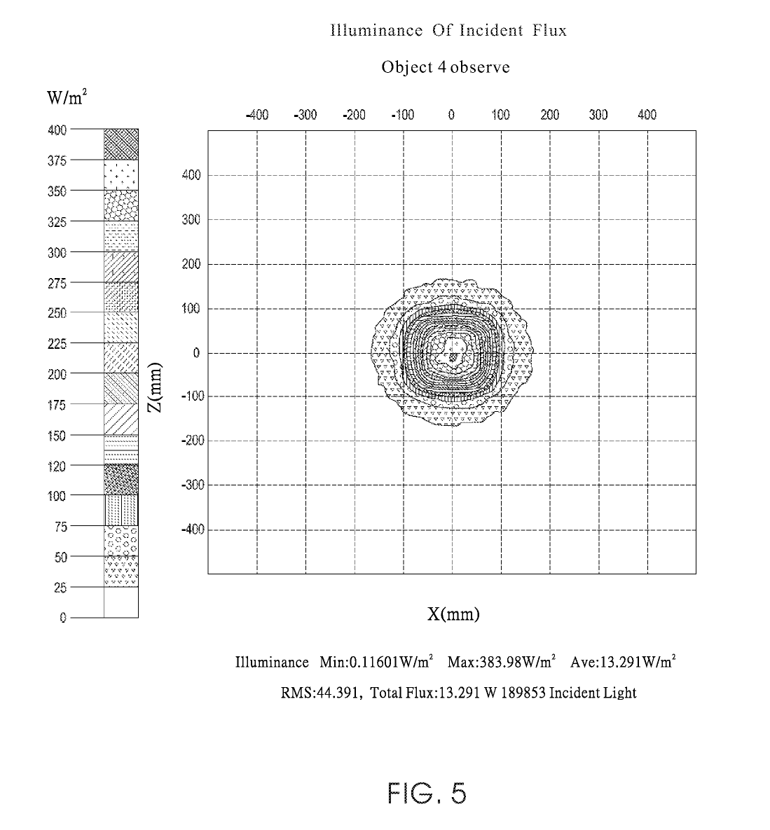

When the light is emitted in the predetermined projecting profile via the light exiting area 131 of the light guiding unit 13, because the predetermined projecting profile comprises at least one straight edge, variable shapes of projecting profiles can be provided, and preferably, those with wider projecting angle. The conformity of the light projected by the light guiding unit is promoted with a great effect in projecting profile accumulation as well. Please refer to FIG. 5 which shows a 2-D distribution of illumination of a lighting device according to an embodiment of the present invention. As shown in FIG. 5, in the present embodiment, the predetermined projecting profile tends to a square. Several lighting device 1 can accumulate their projecting profiles in an array, circle or other way to arrange to form a large illuminating device. When achieving illuminance in the same standard with multiple lighting device to construct a illuminating device, according to the present embodiment, the projecting profile of the lighting device is changed to the predetermined projecting profile for projecting the light from the light guiding unit 13, the number of the lighting device required is less then that constructed by conventional LEDs. So the power consumption is reduced.

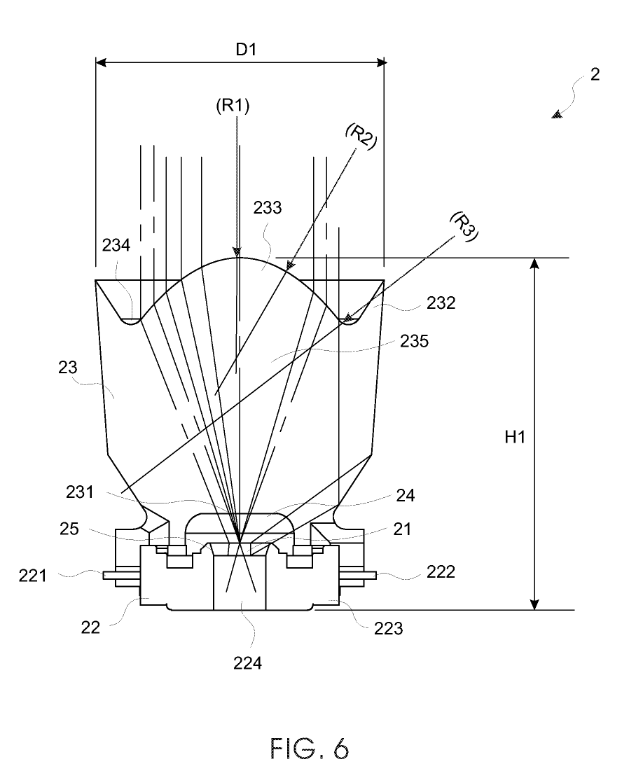

Please refer to FIG. 6, which shows a side view of a lighting device according to another embodiment of the present invention. For illustrate in a simple but clear manner, the same in the both embodiments do not illustrate again. In the present embodiment, the electrical conducting unit 22 of the lighting device 2 is further positioned a heat sink 224 on the place corresponding to the infrared light emitting diode 21 to couple to the infrared light emitting diode 21. The heat dissipation of the infrared light emitting diode 21 is enhanced. Additionally, in the present embodiment, the height H1 of the lighting device 2 is 14.20 mm, the diameter D1, D2 of the light exiting area 135 is 11.65 mm, the curvature radius R1 of the top of the convex lens 133 is 4.67 mm, the curvature radius R2 of the side of the convex lens 133 is 5.74 mm and the curvature radius R3 of the groove 134 is 11.20 mm.

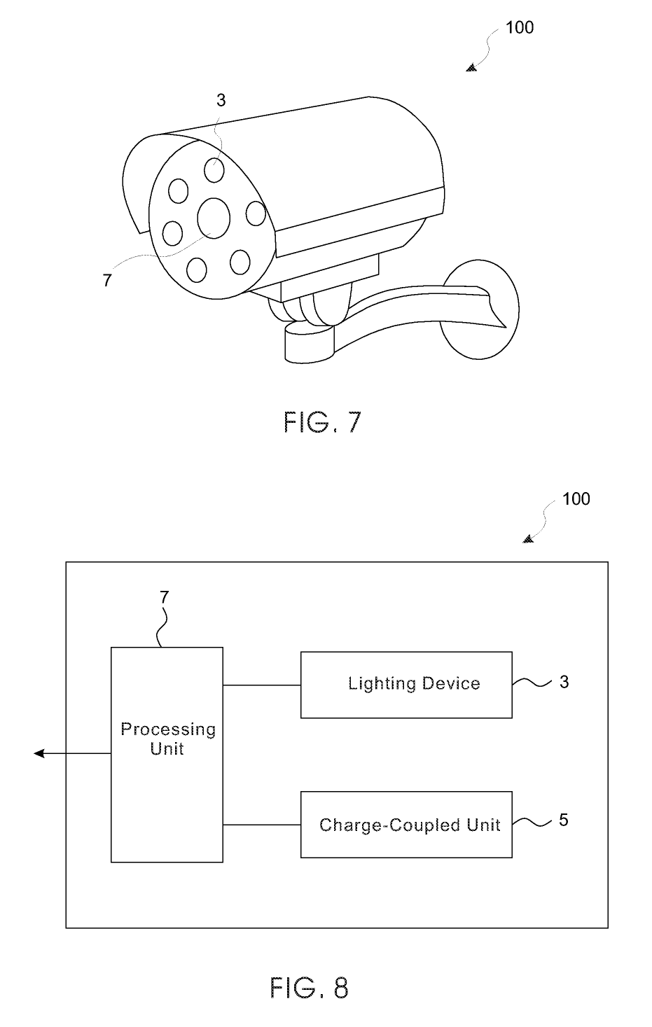

Please refer to FIG. 7 and FIG. 8, wherein FIG. 7 shows a charge-coupled device monitor of an embodiment of the present invention, and FIG. 8 shows a systematic view of the charge-coupled device monitor shown in FIG. 7. The charge-coupled device monitor 100 comprises at least one lighting device 3, at least one charge-coupled unit 5 and a processing unit 7. The processing unit 7 electrically connects to the charge-coupled unit 5. The lighting device 3 can be any one of the lighting device implemented in the previous embodiments. For example, the lighting device 3 comprises an infrared light emitting diode, an electrical conducting unit and a light guiding unit. Here, for clarity, only differences between the present embodiment and previous embodiment are illustrated. The charge-coupled unit 5 corresponds to the lighting device 3 to receive the light emitted by the lighting device 3 in the predetermined projecting profile. When the Photoelectric effect occurs, the light is transformed to at least one electrical signal. After the processing unit 7 receives the electrical signal, an image is transferred according to the electrical signal for watching through a display panel. In the present embodiment, the lighting device 3 can be a LED to emit infrared for the charge-coupled device monitor 100 to be applied in night time.

Hence, as stated above, the projecting profile of the infrared light emitting diode is changed by the light guiding unit to have at least one straight edge. So the accumulation of the projecting profiles is easy to apply to lessen the number of required infrared light emitting diode to sustain illuminance in some standard to reduce power consumption. Thus a lighting device in compliance with environmental consciousness and power saving is provided. Besides, charge-coupled device monitors with such infrared light emitting diode and light guiding unit are able to provide an infrared light emitting diode in compliance with environmental consciousness and long lifetime, so the reliability is promoted.

Although the present invention has been explained by the embodiments shown in the drawings described above, it should be understand to the ordinary skilled person in the art that the present invention is not limited to the embodiments, but rather that various changes or modifications thereof are possible without departing from the spirit of the invention. Accordingly, the scope of the invention shall be determined only by the appended claims and their equivalents.

What is claimed is:

1. A lighting device, comprising:
an infrared light emitting diode, receiving a power to emit a light; and
a light guiding unit, positioned on one side of the infrared light emitting diode, changing the projecting profile of the light to a predetermined projecting profile comprising at least one straight edge.

2. The lighting device according to claim 1, wherein: the predetermined projecting profile is chosen from one of the following shapes comprising square like, rectangle and polygon.

3. The lighting device according to claim 1, wherein: the light guiding unit comprises a light entering area and a light exiting area, the light entering area is next to the infrared light emitting diode, and after the light enters the light guiding unit from the light entering area, the light is projected from the light exiting area in the predetermined projecting profile.

4. The lighting device according to claim 3, wherein: the light exiting area comprises at least one flange and a convex lens forming within the flange.

5. The lighting device according to claim 3, wherein: the diameter of the light exiting area is in the range of 10.8 to 11.8 mm.

6. The lighting device according to claim 4, wherein: the curvature radius of the convex lens is in the range of 5 to 5.3 mm.

7. The lighting device according to claim 4, wherein: the distance between the infrared light emitting diode to the top of the convex lens is in the range of 10.8 to 12 mm.

8. The lighting device according to claim 4, wherein: at least one groove is formed between the flange and the convex lens, the curvature radius of the groove is in the range of 11 to 11.9 mm.

9. The lighting device according to claim 1, wherein the light guiding unit is an acrylic lens.

10. The lighting device according to claim 1, wherein the light guiding unit is a total internal reflection lens.

11. The lighting device according to claim 3, further comprising a buffer positioned between the infrared light emitting diode and the light entering area.

12. The lighting device according to claim 1, further comprising an electrical conducting unit positioned on a side of the infrared light emitting diode, electrically connecting to the infrared light emitting diode to provide the power.

13. The lighting device according to claim 12, wherein the electrical conducting unit further comprises a heat sink coupled to the infrared light emitting diode.

14. The lighting device according to claim 12, wherein the electrical conducting unit further comprising a reflective cup positioned next to the infrared light emitting diode.

15. The lighting device according to claim 12, wherein the electrical conducting unit comprises two electrodes electrically connecting to the cathode and anode of the power respectively.

16. A charge-coupled device monitor, comprising:
at least one lighting device, comprising an infrared light emitting diode, an electrical conducting unit and a light guiding unit, wherein the infrared light emitting diode receives a power to emit a light, the electrical conducting unit is positioned on a side of the infrared light emitting diode, electrically connecting to the infrared light emitting diode to provide the power, the light guiding unit is positioned on another side of the infrared light emitting diode, changing the projecting profile of the light to a predetermined projecting profile, and the predetermined projecting profile comprises at least one straight edge;
at least one charge-coupled unit, receiving the light emitted by the lighting device in the predetermined projecting profile, transforming the light to at least one electrical signal; and
a processing unit, electrically connecting the charge-coupled unit, transferring an image according to the electrical signal.

17. The charge-coupled device monitor according to claim 16, wherein: the predetermined projecting profile is chosen from the shapes: tending to square, rectangle and polygon.

18. The charge-coupled device monitor according to claim 16, wherein: the light guiding unit comprises a light entering area and a light exiting area, wherein the light entering area is next to the infrared light emitting diode, after the light enters the light guiding unit from the light entering area, the light is projected from the light exiting area in the predetermined projecting profile.

19. The charge-coupled device monitor according to claim 18, wherein the light exiting area comprises at least one flange and a convex lens forming within the flange.

20. The charge-coupled device monitor according to claim 18, wherein the diameter of the light exiting area is within 10.8 to 11.8 mm.

21. The charge-coupled device monitor according to claim 19, wherein the curvature radius of the convex lens is within 5 to 5.3 mm.

22. The charge-coupled device monitor according to claim 19, wherein the distance between the infrared light emitting diode to the top of the convex lens is within 10.8 to 12 mm.

23. The charge-coupled device monitor according to claim 19, wherein at least one groove is formed between the flange and the convex lens, and the curvature radius of the groove is within 11 to 11.9 mm.

24. The charge-coupled device monitor according to claim 18, wherein the light guiding unit is a total internal reflection lens.
